(19) United States
(12) Patent Application Publication
(10) Pub. No.: US 2006/0284198 A1
(43) Pub. Date: Dec. 21, 2006

(54) Light emitting diode with larger illumination area

(76) Inventor: Fu-Kuo Huang, Tucheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/400,261

(22) Filed: Apr. 10, 2006

(30) Foreign Application Priority Data
Jun. 16, 2005 (TW) 094120001
Apr. 4, 2006 (TW) 095111990

(51) Int. Cl. H01L 33/00

(52) U.S. Cl. 257/98

(57) ABSTRACT

The present invention relates to a light emitting diode with larger illumination area that includes a LED chip and a shielding layer. The shielding layer is disposed over an incident plane of the LED chip and its length is longer, equal to or shorter than the length of the incident plane of the LED chip. Thus diffraction generates by light emitted from the LED chip passing through the shielding layer so as to increase illumination area of the LED with more uniform brightness.

### BACKGROUND OF THE INVENTION

The present invention relates to a light emitting diode, especially to a light emitting diode that increases illumination area of light source.

Since there is an illumination device, the most common light source is a point source such as tungsten lamps. However, conventional tungsten lamps with higher power consume quite a lot of energy. Thus people in industry or research institute in various countries are dedicated to developing new light source for improving shortcomings of conventional tungsten lamps. Therefore, high-luminous LED chip and the related lamp design is invented to meet such kind of requirements. LED becomes new type point source.

Light emitting diode (LED) is a fine solid-state light source made of semiconductor material. The device that turns electricity into light features on the compact structure, with long lifetime, low driving voltage, fast reaction, and good shock resistance. It can also be applied in various appliances with light weight and compact design and is quite popular in our daily lives. For example, LED is applied to indoor illumination devices, indicator lights on keyboard, center high-mounted stop lamps, outdoor LED displays and traffic signs.

Refer to FIG. 1A, a SMD (surface mounting device) type LED 10′ is revealed. A LED chip 20′ works as light source of the SMD type LED 10′. Because LED chip is a point source, the incident angle is quite small. Thus light beam 30′ from the light source moves linearly, focusing in center part while the surrounding is darker. Therefore, the illumination area of the LED 10′ can't be enlarged, and the illumination area is shown as FIG. 1B. Moreover, while using LED illumination devices, once users want to have better illumination area and effect, it is necessary to install more numbers of LED inside the devices because the illumination area of the LED is narrower. Thus the cost of illumination devices is increased.

There is a need to have a kind of LED with larger illumination area so as to improve shortcomings of conventional LED that is unable to become a surface light source with lower cost.

### SUMMARY OF THE INVENTION

Therefore it is a primary object of the present invention to provide a light emitting diode with larger illumination area that increases illumination area of light emitting diode.

It is another object of the present invention to provide a light emitting diode with larger illumination area that is suitable to be applied to LED with different packages.

A light emitting diode with larger illumination area in accordance with the present invention includes a shielding layer disposed over an incident plane on a LED chip and length of the shielding layer may be longer, shorter or equal to that of the incident plane of the LED chip. Thereby, light emitted from the LED chip passes through the shielding layer and has diffraction so as to make LED with different packages have larger illumination area. Furthermore, the shielding layer includes at least an aperture etched thereof, or metal particles mixed with transparent particles, printed on the LED chip so as to make light from the LED chip passes through a single-slit, double-slit or multiple slit formed by the aperture or transparent particles on the shielding layer to generate new wavefronts and improves shadow on near-field of the original diffraction. Thus an increased illumination area is formed on near field. Therefore, the LED according to the present invention becomes a bottom lighting type back light source.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a schematic drawing of a SMD-type (surface mounting device) light emitting diode;

FIG. 1B is a schematic drawing showing illumination area of conventional light emitting diode;

FIG. 2 is a schematic drawing of an embodiment of a light emitting diode in accordance with the present invention;

FIG. 3 is a schematic drawing showing diffraction generated by a shielding layer of an embodiment in accordance with the present invention;

FIG. 4 is a schematic drawing of another embodiment of a light emitting diode in accordance with the present invention;

FIG. 5 is a schematic drawing of a further embodiment of a light emitting diode in accordance with the present invention;

FIG. 6 is a schematic drawing of a further embodiment of a light emitting diode in accordance with the present invention;

FIG. 7 is a schematic drawing of a further embodiment of a light emitting diode in accordance with the present invention;

FIG. 8 is a schematic drawing of a further embodiment of a light emitting diode in accordance with the present invention;

FIG. 9 is a schematic drawing of a further embodiment of a light emitting diode in accordance with the present invention;

FIG. 10 is a schematic drawing showing diffraction generated by a shielding layer of another embodiment in accordance with the present invention;

FIG. 11 is a schematic drawing of a further embodiment of a light emitting diode in accordance with the present invention;

FIG. 12 is a schematic drawing of a further embodiment of a light emitting diode in accordance with the present invention;

FIG. 13 is a schematic drawing showing diffraction generated by a shielding layer of a further embodiment in accordance with the present invention;

FIG. 14 is a schematic drawing of a further embodiment of a light emitting diode in accordance with the present invention;

FIG. 15 is a schematic drawing of a further embodiment of a light emitting diode in accordance with the present invention;

FIG. 16 is a schematic drawing showing diffraction generated by a shielding layer of a further embodiment in accordance with the present invention;

FIG. 17 is a schematic drawing of a transparent particle of an embodiment in accordance with the present invention;

FIG. 18 is a schematic drawing of a transparent particle of another embodiment in accordance with the present invention;

FIG. 19 is a schematic drawing of a further embodiment of a light emitting diode in accordance with the present invention;

FIG. 20A is a schematic drawing showing illumination area of a light emitting diode in accordance with the present invention;

FIG. 20B is a schematic drawing showing illumination area of a light emitting diode in accordance with the present invention; and

FIG. 20C is a schematic drawing showing illumination area of a light emitting diode in accordance with the present invention.

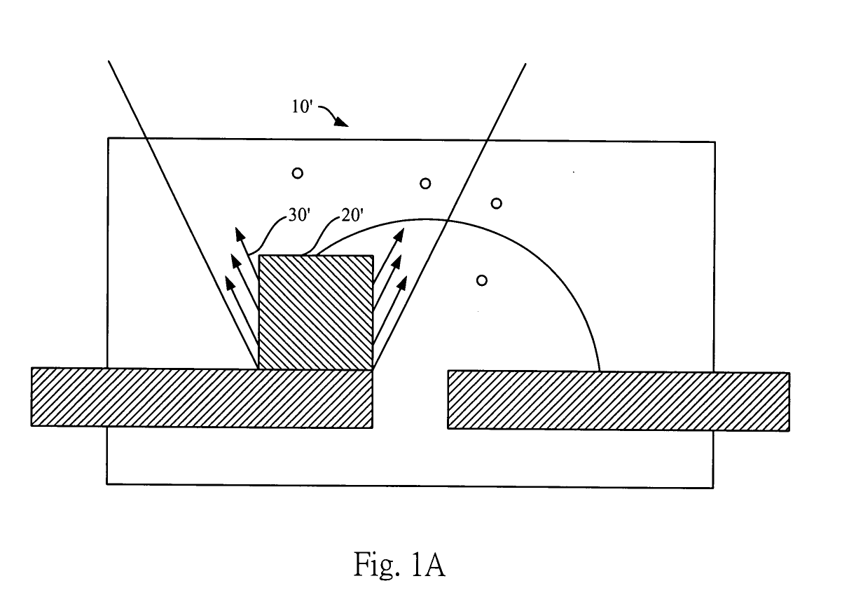

### DETAILED DESCRIPTION OF THE PREFERRED EMBODIMENT

The present invention provides a LED with larger illumination area to overcome above disadvantages.

The following SMD(surface mounting device) LED, lamp LED and PCB(printed circuit board) LED are taking as examples to explain the present invention. The present invention is applied to LED with different packages so as to make illumination area of point source LED change into illumination area of surface light source.

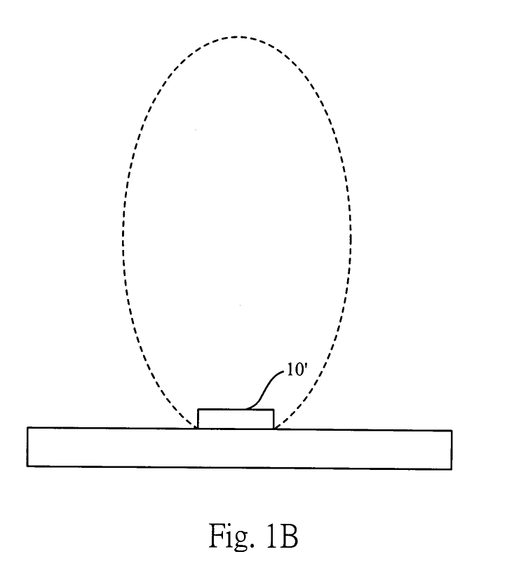

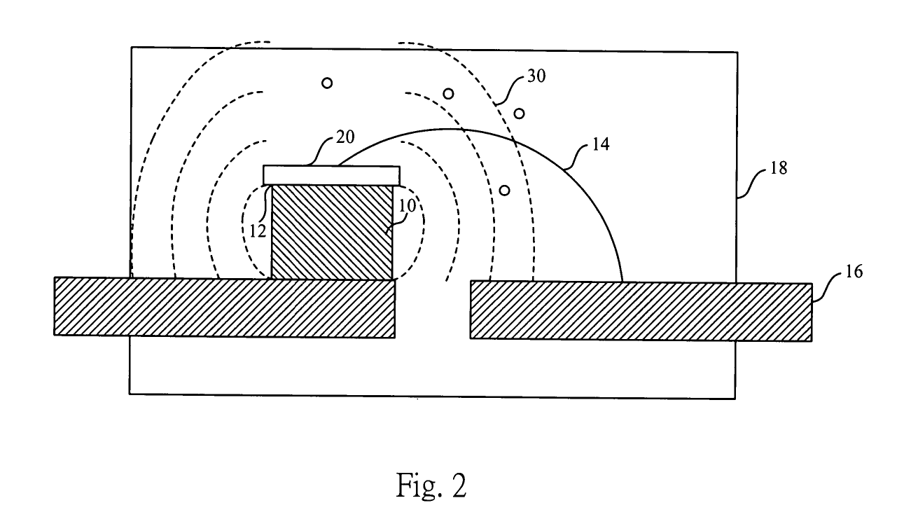

Refer to FIG. 2, a LED in accordance with the present invention consists of a LED chip 10 and a shielding layer 20 that is disposed over an incident plane 12 on the LED chip 10. The length of the shielding layer 20 is longer than that of the incident plane 12 on the LED chip 10. When light emitted from the LED chip 10 arrives the shielding layer 20, a first wavefront 30 caused by diffraction is generated. After various portions of the first wavefront 30 in spherical shape propagating a certain distance, the light waves interacts with one another to form enlarged illumination area so as to achieve the purpose of increasing the illumination area. By interfering of the first wavefront 30 coming from interaction of the first wavefront 30, the brightness of the LED light source is uniform, as shown in FIG. 3. In this embodiment, the length of the shielding layer 20 is larger than that of the incident plane 12 on the LED chip 10 while the length of the shielding layer 20 can also be equal to or smaller than that of the incident plane 12 on the LED chip 10.

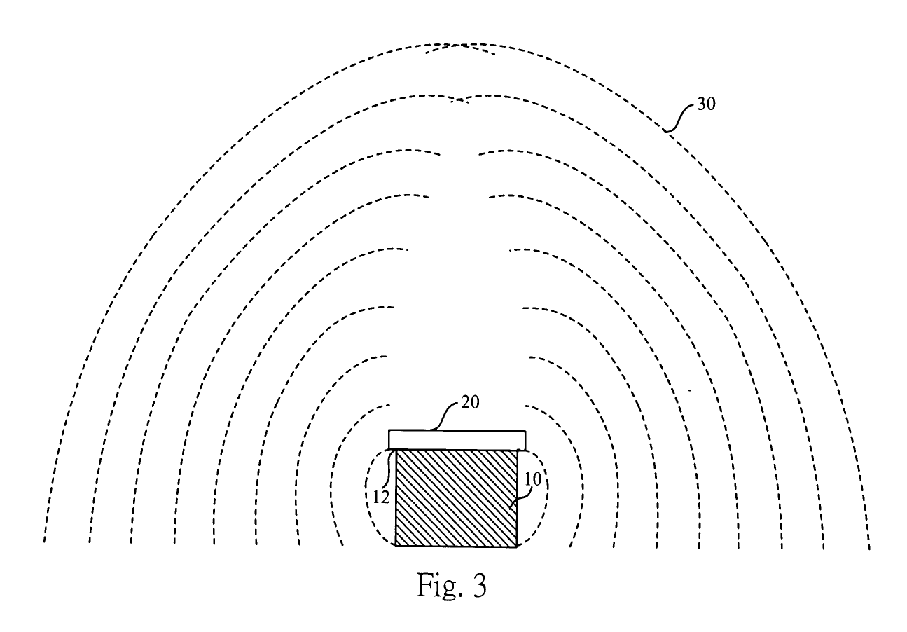

Refer to FIG. 4, another embodiment of the present invention is disclosed. The difference between this embodiment and the embodiment in FIG. 2 is in that in FIG. 2, the shielding layer 20 is disposed on top of the LED chip 10 inside a package 18 while the shielding layer 20 in FIG. 4 is disposed on top of the package 18. In this embodiment, the LED chip 10 is arranged in the package 18 and the shielding layer 20 is disposed on top of the package 18, over the LED chip 10. Thus the LED chip 10 generates larger illumination area through the shielding layer 20 by diffraction and interfering of the front wavefront 30.

The shielding layer 20 is made from gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or combinations of above material. When a wire 14 is electrically connected with a SMD electrode 16, the LED chip 10 from a conductive layer by the shielding layer 20 made from conductive material so as to generate total internal refraction between the shielding layer 20 and the SMD electrode 16, like mirrors, as well as the first wavefront 30 of diffraction. After propagating a certain distance, the first wavefront 30 interacts to form illumination area of surface light source. And by interference of the first wavefront 30, the brightness is more uniform.

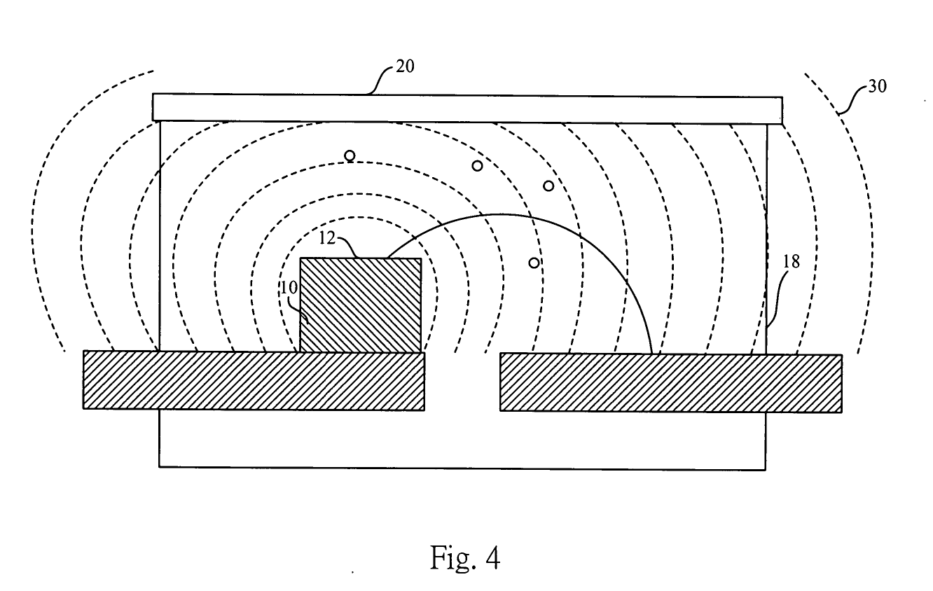

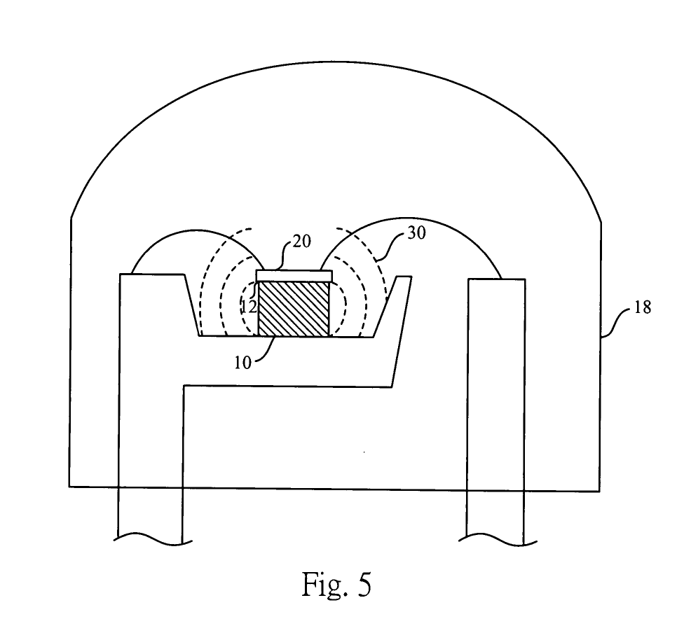

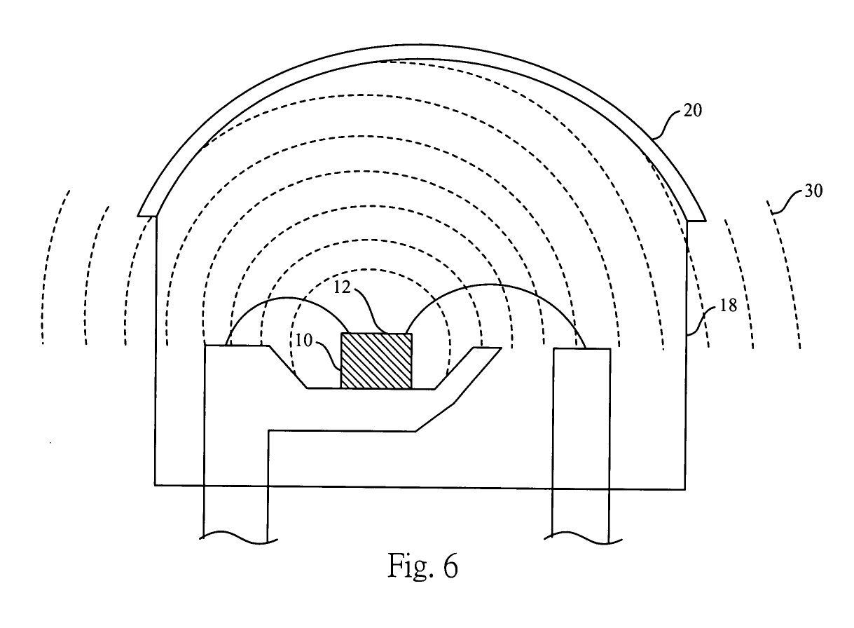

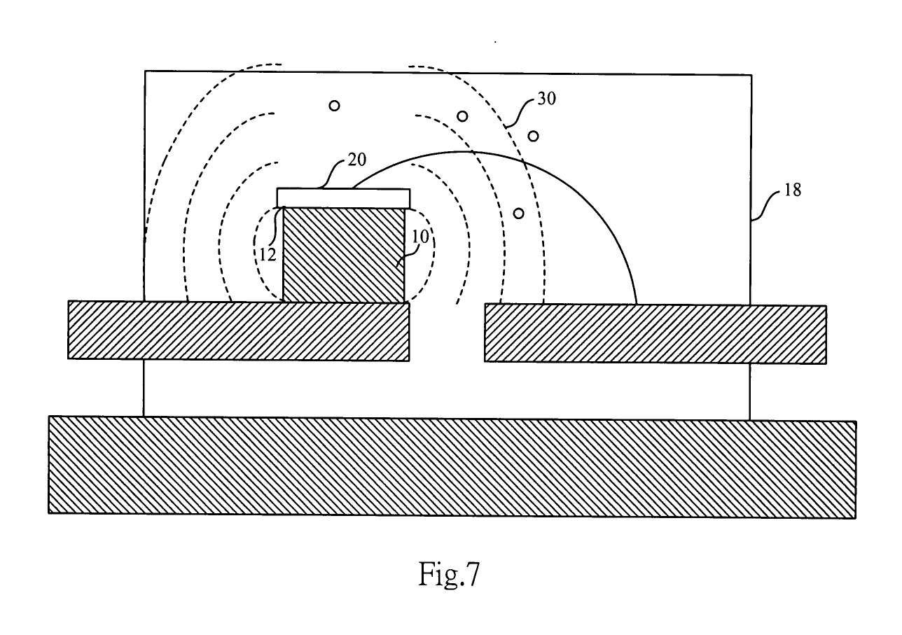

Refer to FIG. 5 & FIG. 6, the present invention are applied to a lamp LED. In FIG. 7 & FIG. 8, the present invention are applied to printed circuit board type LED. The shielding layer 20 is mounted above an incident plane 12 of the LED chip 10 of the lamp LED. Or the shielding layer 20 is mounted above an incident plane 12 of the LED chip 10 of a PCB (printed circuit board) LED. When light from the LED chip 10 passes through the shielding layer 20, the first wavefront 30 of diffraction is generated so as to increase illumination area of the lamp LED or the PCB LED. That is the area formed by diffraction and interfering of the first wavefront 30.

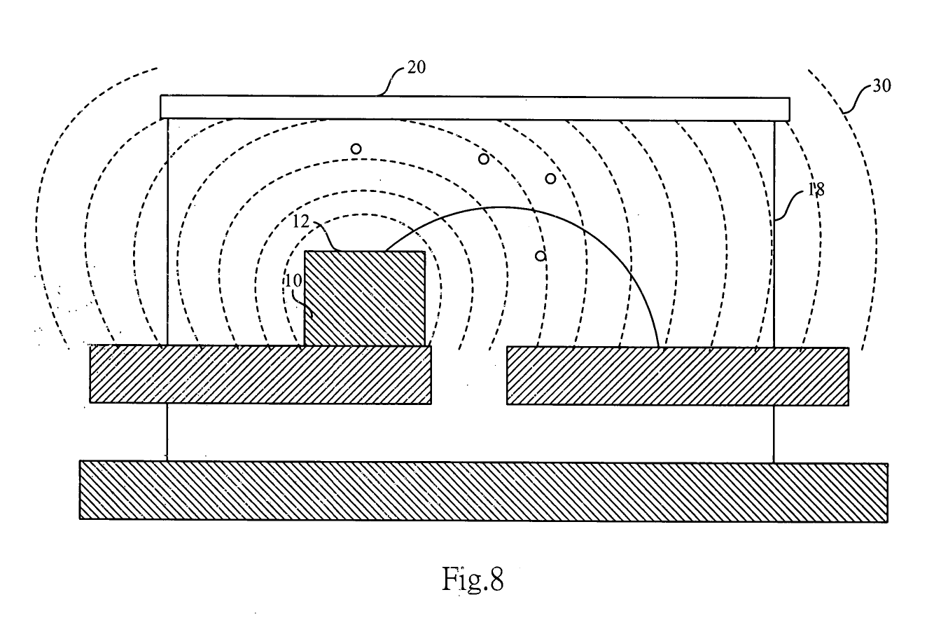

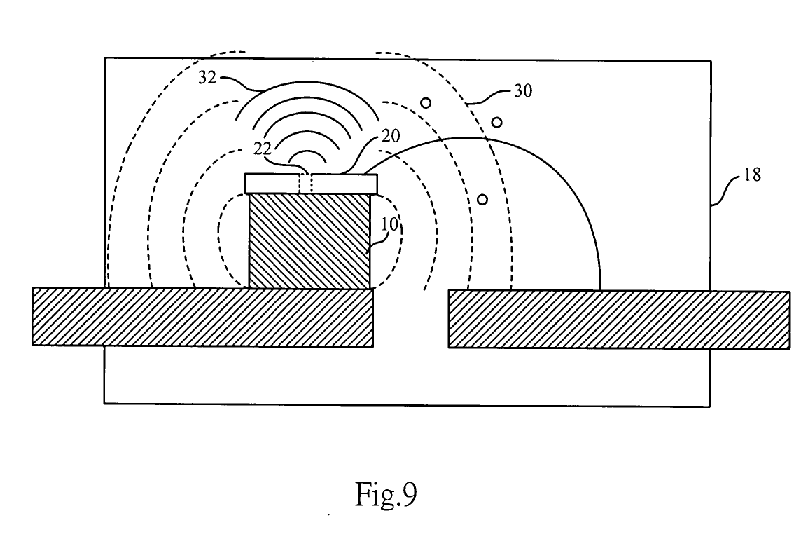

Refer to FIG. 9, a further embodiment is disclosed. The difference between this embodiment and the embodiment in FIG. 2 is in that the shielding layer 20 in FIG. 2 is disposed on the incident plane 12 of the LED chip 10 and the shielding layer 20 in FIG. 9 further having an aperture 22 that is made by an etching process. In this embodiment, the shielding layer 20 is disposed with the aperture 22 so as to make light from the LED chip 10 pass through the aperture 22 to generate a second wavefront 32 from single-slit diffraction. Thereby, the second wavefront 32 and the first wavefront 31 make the light source to have larger illumination area during a shorter distance. The increased illumination area formed by the first wavefront 31 as well as the second wavefront 32 are shown in FIG. 10. The first wavefront 31 is generated on two sides of the LED chip 10 while the second wavefront 32 is generated by single-slit diffraction through the aperture 22. The two wavefronts 31, 32 interfere with each other so as to make brightness uniform.

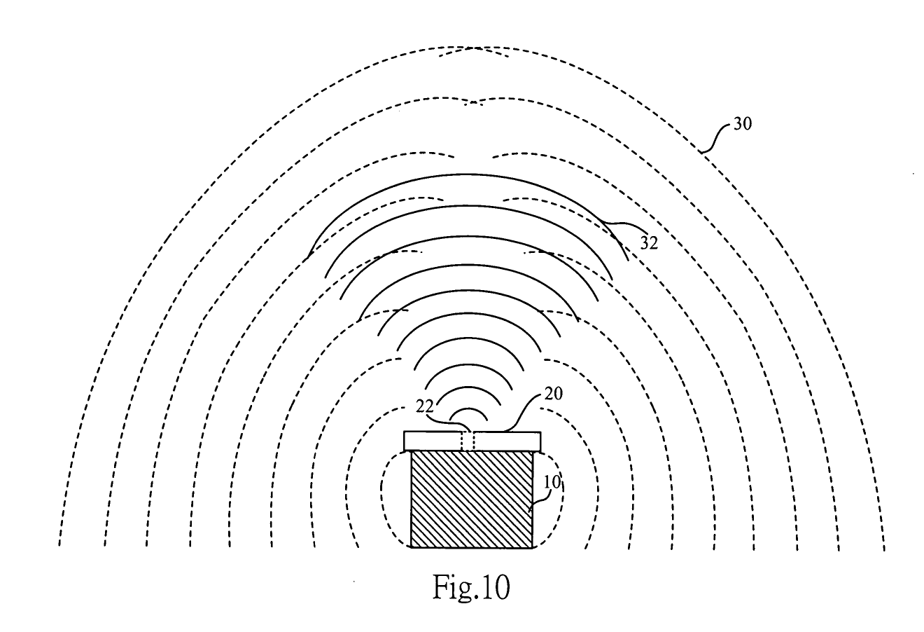

As shown in FIG. 11, the shielding layer 20 with the aperture 22 is able to be arranged above the package 18 so that the second wavefront 32 generated by single-slit diffraction through the aperture 22, in combination with the first wavefront 30 to form an enlarged illumination area with uniform brightness. The shielding layer 20 is made from gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or combinations of above materials.

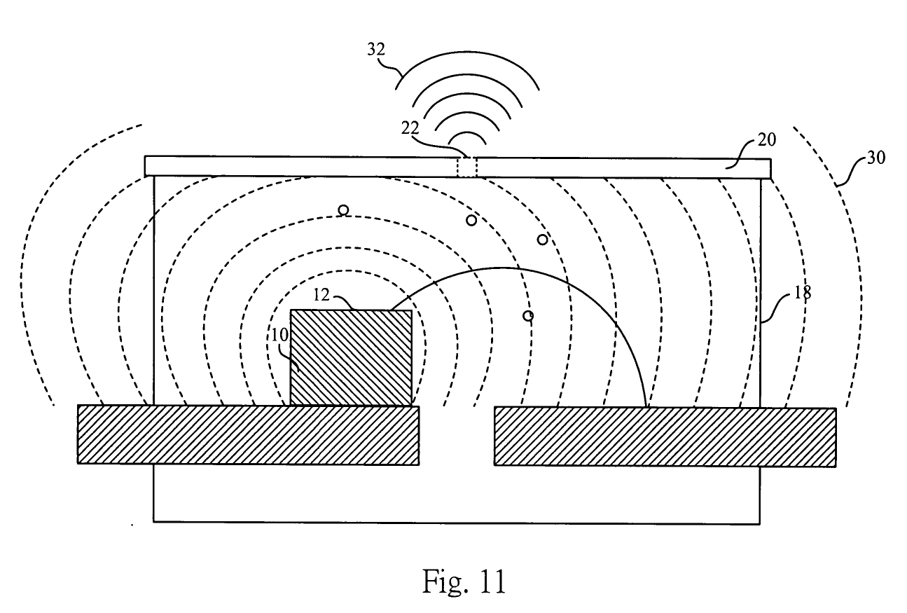

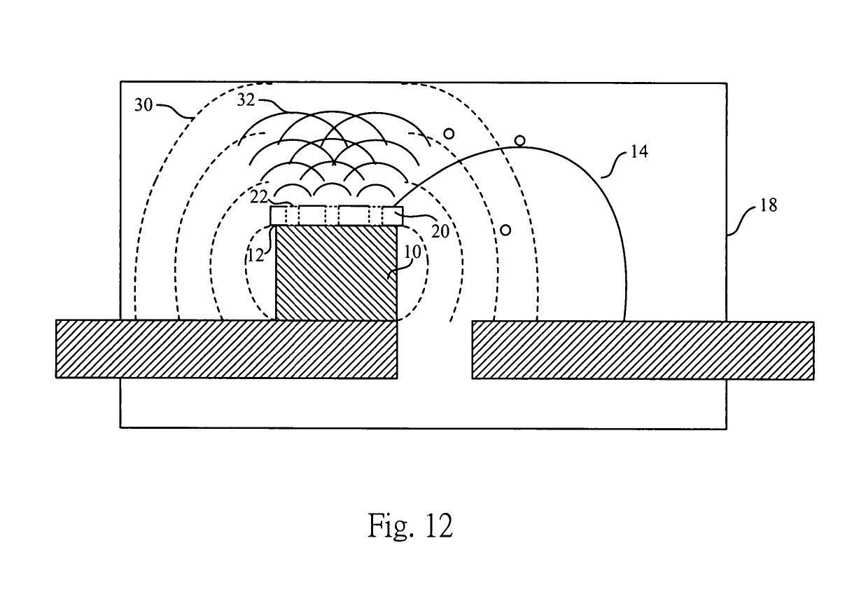

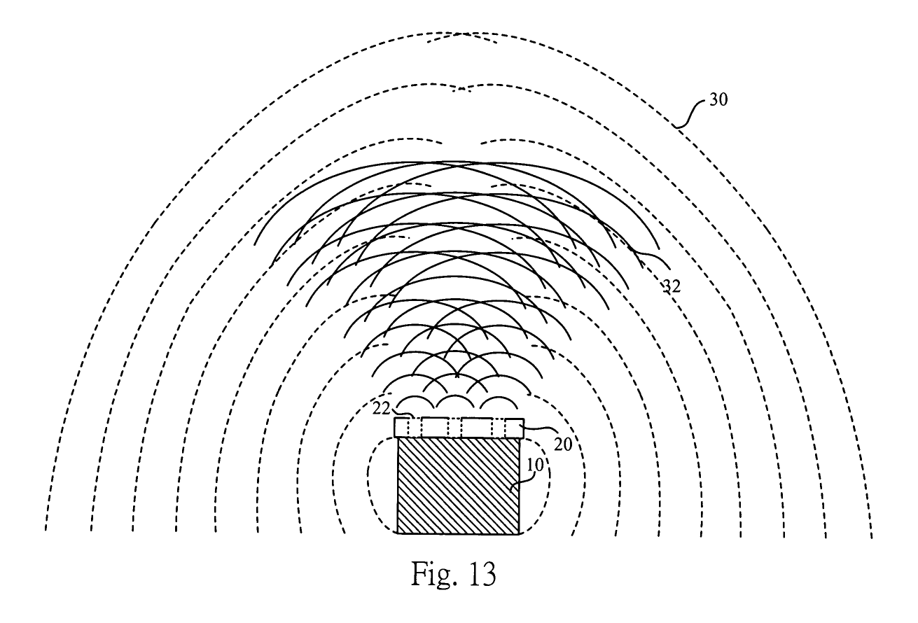

Furthermore, refer to FIG. 12 & FIG. 14, the shielding layer 20 is mounted with a plurality of apertures 22. In FIG. 12, the shielding layer 20 is disposed on the incident plane 12 of the LED chip 10. The first wavefront 30 is generated by light from LED chip 10 passing through the shielding layer 20 and the second wavefront 32 formed by single-slit diffraction through the apertures 22. The first wavefront 30 and the second wavefront 32 are interfered with each other to form an increased illumination area. As shown in FIG. 13, the first wavefront 30 interacts with the second wavefront 32 to form a large illumination area on space near the LED chip 10. The shielding layer 20 in FIG. 14 is installed above the package 18 and a plurality of second wavefronts 32 are generated by multiple-slit diffraction through the apertures 22. The shielding layer 20 is made from gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or combinations of above material. The apertures 22 are formed on the shielding layer 20 by a etching process or a printed process and are able to be mass-produced.

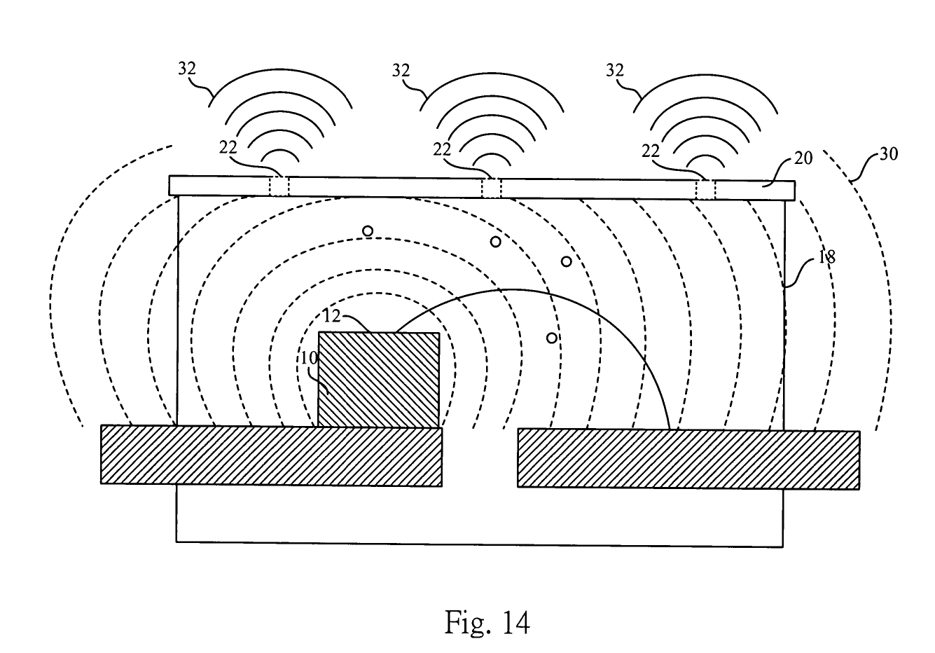

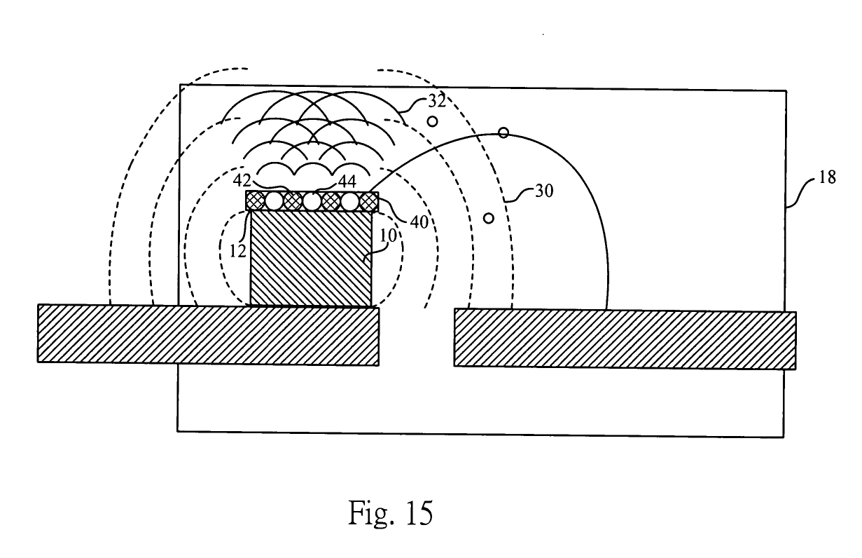

Refer to FIG. 15, a further embodiment is disclosed. The difference between this embodiment and the embodiment in FIG. 12 is in that the shielding layer 20 in FIG. 12 is disposed with a plurality of apertures 22 by the etching process while the shielding layer 40 in FIG. 15 is formed by a screen printing process. Metal particles 42 are mixed transparent particles 44, through the screen printing process to form the shielding layer 40. The light from the LED chip 10 passes through the transparent particle 44 inside the shielding layer 40 to generate the second wavefront 32 by multiple slits formed by the transparent particle 44. The first wavefront 30 generated by the shielding layer 40 works together with the second wavefront 32 from the transparent particle 44 so as to make an enlarged illumination area formed on near field. Furthermore, the brightness of this area is uniformed by interference of the first wavefront 30 with the second wavefront 32, as shown in FIG. 16.

After the light from the LED passing the multiple slits, a new wavefront generated through each of the slits. Each wavefront produces spherical waves that interfere with each other. Interference includes constructive interference and destructive interference. A bright fringe generated by the constructive interference is for compensating shadow of near-field of the original diffraction so as to form a bottom lighting type back light source with uniform brightness.

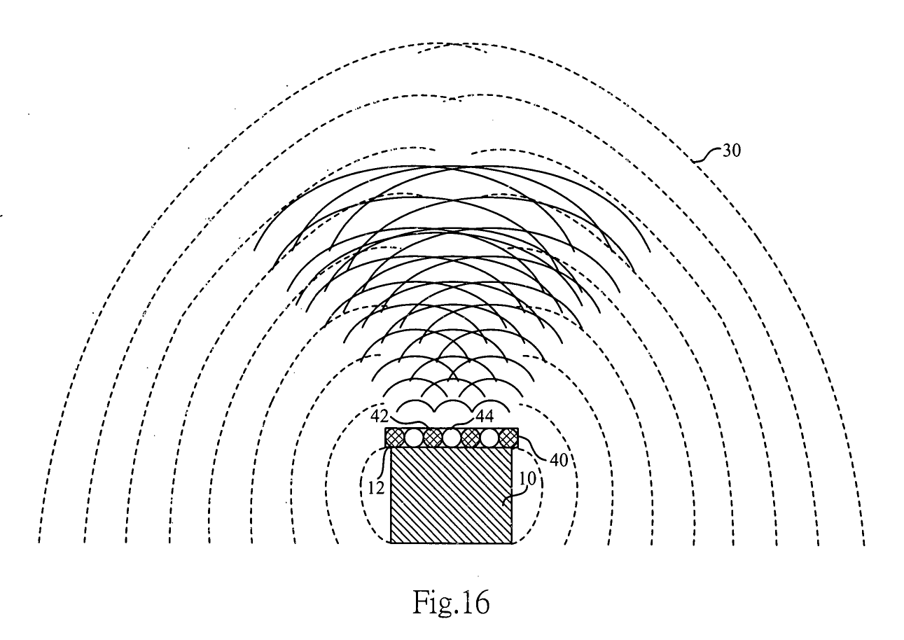

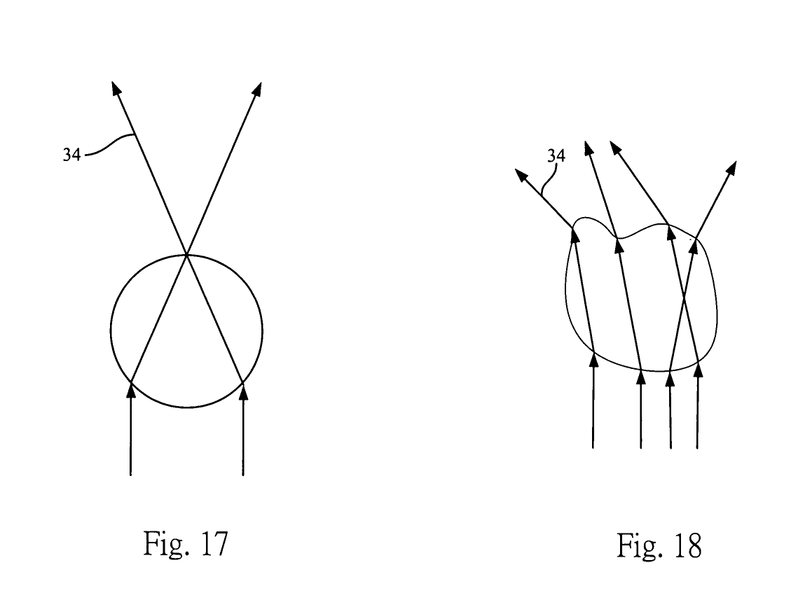

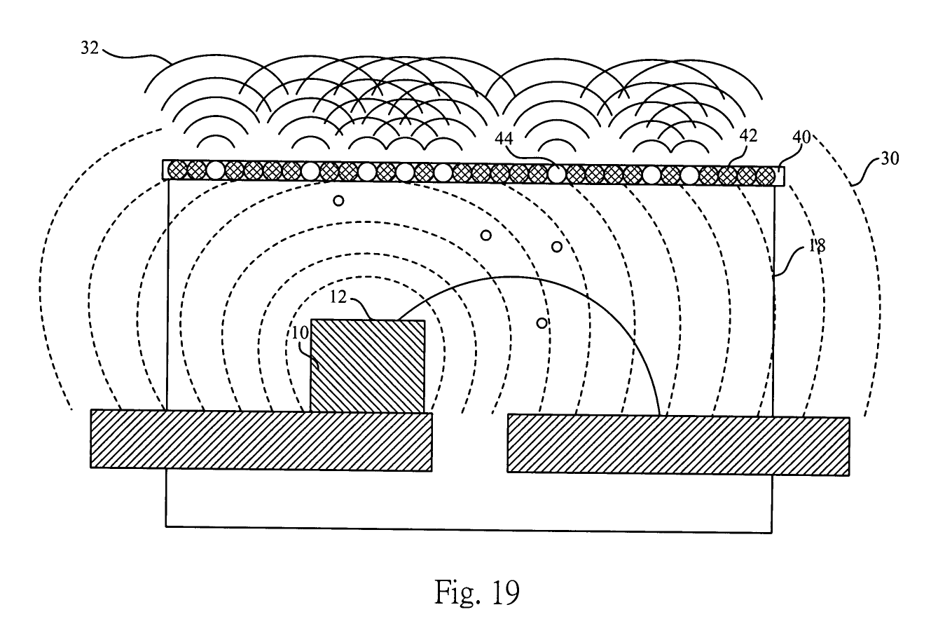

The transparent particles 44 are made from metal oxides, sulfide, fluorescent powder, or combination of above materials and its shape can be spherical or free form, as shown in FIG. 17 & FIG. 18. Refer to FIG. 17, light rays 34 pass the spherical transparent particle 44 and interact at surface of the transparent particle 44 so that the light 34 diffuses to form slit-diffraction-like wavefront after passing the transparent particle 44. In FIG. 18, after the light 34 passing through he irregular-shaped transparent particle 44, each point generates light emitted toward different directions to form slit-diffraction-like wavefront by light diffusion. Moreover,

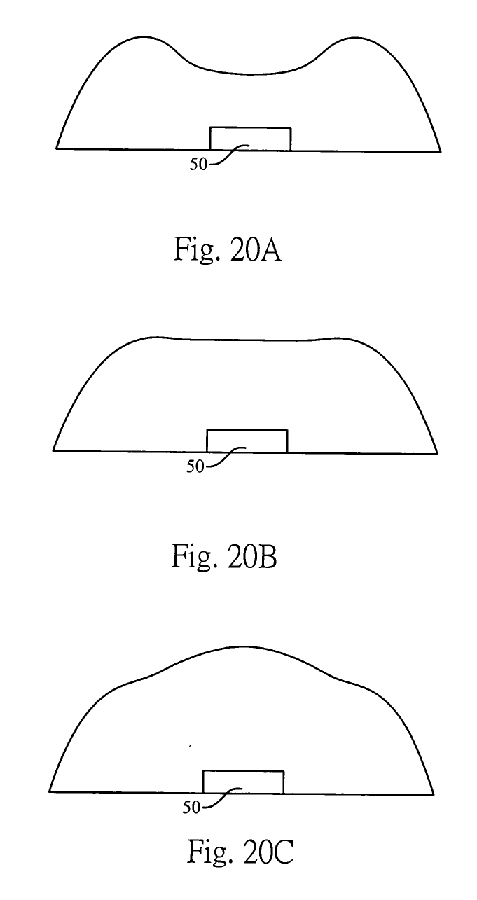

Refer from FIG. 20A to FIG. 20C, each represents a LED 50 in accordance with the present invention with different illumination area caused by a shielding layer having different number of apertures or different amount of transparent particles. Refer to FIG. 20A, the illumination area is valley-shaped with a bit concave in the middle part because the shielding layer of the LED 50 is disposed with a few apertures or a few amount of transparent particles. In the FIG. 20B, the illumination area looks like a plateau with a flat middle part due to proper amount of apertures or transparent particles in the shielding layer of the LED 50. With reference of FIG. 20 C, owing to lots of apertures or large amount of transparent particles in the shielding layer of the LED 50, the middle part of the illumination area is projective and looks like a small hill.

Moreover, interference between the two wavefronts 30, 32 provides uniform brightness. Thus an LED with larger illumination area according to the present invention becomes a low-cost surface light source by light diffraction and interference, working as a low-cost a bottom lighting type back light source.

In summary, the present invention relates to a light emitting diode with larger illumination area that includes a LED chip and a shielding layer and the illumination area is increased by diffraction generated from light passing through the shielding layer. The shielding layer is disposed with at least an aperture or transparent particles so that light from the LED chip passes through a single-slit, double-slit or multiple slit formed by the aperture or transparent particles to form new point sources and generate new wavefronts. Thus an increased illumination area is formed on near field of LED light source. Moreover, by interference between wavefronts, the brightness is uniformed so that the present invention works as a bottom lighting type back light source. Furthremore, the present invention is applied to LED with different packages to make the brightness uniform and reduce numbers of LED inside illumination devices so as to save cost.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A light emitting diode with larger illumination area comprising:
a light emitting diode chip; and
a shielding layer disposed over an incident plane of the light emitting diode chip;
wherein the length of the shielding layer is longer than the length of the incident plane of the light emitting diode chip.

2. The device as claimed in claim 1, wherein the shielding layer is disposed over a package of the light emitting diode chip.

3. The device as claimed in claim 1, wherein the light emitting diode chip is packaged into a lamp LED(light emitting diode), PCB(printed circuit board) LED, front light LED, side light LED, or SMD (surface mounting device) LED.

4. The device as claimed in claim 1, wherein the shielding layer is made from conductive material.

5. The device as claimed in claim 4, the conductive material is gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or one of combinations of above materials.

6. The device as claimed in claim 1, wherein at least an aperture or a slit is disposed on the shielding layer.

7. The device as claimed in claim 6, wherein the aperture or the slit is disposed on the shielding layer by an etching process or a printing process.

8. The device as claimed in claim 1, wherein the shielding layer having a plurality of metal particles mixing with at least one transparent particle.

9. The device as claimed in claim 8, wherein the transparent particle is made from metal oxides, sulfide, fluorescent powder, or one of combinations of above materials.

10. The device as claimed in claim 8, wherein the transparent particle is spherical or free form.

11. The device as claimed in claim 8, wherein a manufacturing process of the shielding layer comprising an etching process, screen printing, planographic printing, letterpress printing, intaglio printing or transfer printing process.

12. A light emitting diode with larger illumination area comprising:
a light emitting diode chip; and
a shielding layer disposed over an incident plane of the light emitting diode chip;
wherein the length of the shielding layer is shorter than the length of the incident plane of the light emitting diode chip.

13. The device as claimed in claim 12, wherein the shielding layer is disposed over a package of the light emitting diode chip.

14. The device as claimed in claim 12, wherein the light emitting diode chip is packaged into a lamp LED(light emitting diode), PCB(printed circuit board) LED, front light LED, side light LED, or SMD (surface mounting device) LED.

15. The device as claimed in claim 12, wherein the shielding layer is made from conductive material.

16. The device as claimed in claim 15, the conductive material is gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or one of combinations of above materials.

17. The device as claimed in claim 12, wherein at least an aperture or a slit is disposed on the shielding layer.

18. The device as claimed in claim 17, wherein the aperture or the slit is disposed on the shielding layer by an etching process or a printing process.

19. The device as claimed in claim 12, wherein the shielding layer having a plurality of metal particles mixing with at least one transparent particle.

20. The device as claimed in claim 19, wherein the transparent particle is made from metal oxides, sulfide, fluorescent powder, or one of combinations of above materials.

21. The device as claimed in claim 19, wherein the transparent particle is spherical or free form.

22. The device as claimed in claim 19, wherein a manufacturing process of the shielding layer comprising an etching process or a screen printing process.

23. A light emitting diode with larger illumination area comprising:
a light emitting diode chip; and
a shielding layer disposed over an incident plane of the light emitting diode chip;
wherein the length of the shielding layer is equal to the length of the incident plane of the light emitting diode chip.

24. The device as claimed in claim 23, wherein the shielding layer is disposed over a package of the light emitting diode chip.

25. The device as claimed in claim 23, wherein the light emitting diode chip is packaged into a lamp LED(light emitting diode), PCB(printed circuit board) LED, front light LED, side light LED, or SMD (surface mounting device) LED.

26. The device as claimed in claim 23, wherein the shielding layer is made from conductive material.

27. The device as claimed in claim 26, the conductive material is gold, silver, copper, aluminum, titanium oxide, silicon oxide, zinc oxide, lead oxide, barium oxide, aluminum oxide, barium titanate, aluminate, silicate, strontium aluminate, titanate, aluminium silicate, zinc sulfide, or one of combinations of above materials.

28. The device as claimed in claim 23, wherein at least an aperture or a slit is disposed on the shielding layer.

29. The device as claimed in claim 28, wherein the aperture or the slit is disposed on the shielding layer by an etching process or a printing process.

30. The device as claimed in claim 23, wherein the shielding layer having a plurality of metal particles mixing with at least one transparent particle.

31. The device as claimed in claim 30, wherein the transparent particle is spherical or free form.

32. The device as claimed in claim 30, wherein the transparent particle is made from metal oxides, sulfide, fluorescent powder, or one of combinations of above materials.

33. The device as claimed in claim 30, wherein a manufacturing process of the shielding layer comprising an etching process or a screen printing process.
